(19) United States
(12) Patent Application Publication
(10) Pub. No.: US 2007/0064392 A1
(43) Pub. Date: Mar. 22, 2007

(54) Heat dissipating system

(76) Inventors: Chien-Jung Chen, Kaohsiung Hsien (TW); Te-Tsung Chen, Kaohsiung Hsien (TW); Chih-Tsung Hsu, Kaohsiung Hsien (TW)

Correspondence Address: GALLAGHER & LATHROP, A PROFESSIONAL CORPORATION, 601 CALIFORNIA ST, SUITE 1111, SAN FRANCISCO, CA, 94108, US

(21) Appl. No.: 11/392,090

(22) Filed: Mar. 28, 2006

(30) Foreign Application Priority Data
Sep. 21, 2005 (TW) 094216232

(51) Int. Cl. H05K 7/20

(52) U.S. Cl. 361/699

(57) ABSTRACT

A heat dissipating system adapted for cooling an electronic device includes: a heat sink adapted to be connected to the electronic device; a driving mechanism; a cooling mechanism; a coolant circulating conduit adapted for receiving a coolant therein, and connected to the heat sink, the driving mechanism, and the cooling mechanism such that the driving mechanism drives circulation of the coolant in the coolant circulating conduit through the heat sink and the cooling mechanism; and a fan unit disposed rotatably in the heat sink, and driven to rotate by the coolant flowing through the heat sink.

### CROSS-REFERENCE TO RELATED APPLICATION

This application claims priority of Taiwanese application no. 094216232, filed on Sep. 21, 2005.

### BACKGROUND OF THE INVENTION

1. Field of the Invention

This invention relates to a heat dissipating system, more particularly to a heat dissipating system with a fan unit in a heat sink for cooling an electronic device.

2. Description of the Related Art

As technology advances in the field of computers, performance of the computer has become more and more powerful. Therefore, considerable heat is generated by electronic devices, such as a central processing unit (CPU), of the computer, thereby resulting in a high temperature. The high temperature can cause improper shut down of the computer and damage to the data stored in the computer. Thus, heat dissipation is a major concern for computer manufacturers.

FIG. 1 shows a conventional heat dissipating device 1 that includes a heat sink 11, a coolant 12, a driving mechanism 13, a cooling mechanism 14, and a conduit 112 allowing the coolant 12 to flow therein and connected to the heat sink 11 and the driving mechanism 13.

The heat sink 11 includes a body 111 heat-exchangably connected to an electronic device 100, and defines an inner space in the body 111. The coolant 12 is received in the inner space of the heat sink 11, and flows through the inner space of the heat sink 11 so as to carry the heat from the electronic device 100.

The driving mechanism 13 is used to circulate the coolant 12 in the heat dissipating system 1.

The cooling mechanism 14 includes a plurality of heat dissipating fins 142 spaced apart from each other and connected to a tortuous section 141 of the conduit 112.

In operation, the heat generated by the electronic device 100 is transferred to the body 111 of the heat sink 11, and is carried by the coolant 12 to the cooling mechanism 14 so as to be dissipated thereat. The heat dissipating fins 142 of the cooling mechanism 14 contact the tortuous section 141 of the conduit 112 so as to facilitate heat dissipation. With the circulation of the coolant 12, the heat generated by the electronic device 100 is dissipated.

As described above, because of the advance of technology, there is a need in the art to provide a heat dissipating system with superior heat-exchanging efficiency as compared to the prior art.

### SUMMARY OF THE INVENTION

Therefore, the object of the present invention is to provide a heat dissipating system for cooling an electronic device that has a higher heat dissipating efficiency as compared to the prior art.

According to this invention, a heat dissipating system adapted for cooling an electronic device comprises: a heat sink adapted to be connected to the electronic device for absorbing heat from the electronic device; a driving mechanism; a cooling mechanism; a coolant circulating conduit adapted for receiving a coolant therein, and connected to the heat sink, the driving mechanism, and the cooling mechanism such that the driving mechanism drives circulation of the coolant in the coolant circulating conduit through the heat sink and the cooling mechanism so as to transfer heat from the heat sink to the cooling mechanism through the coolant; and a fan unit disposed rotatably in the heat sink, and driven to rotate by the coolant flowing through the heat sink.

### BRIEF DESCRIPTION OF THE DRAWINGS

Other features and advantages of the present invention will become apparent in the following detailed description of the preferred embodiment of this invention, with reference to the accompanying drawings, in which:

FIG. 1 is a schematic view of a conventional heat dissipating device; and

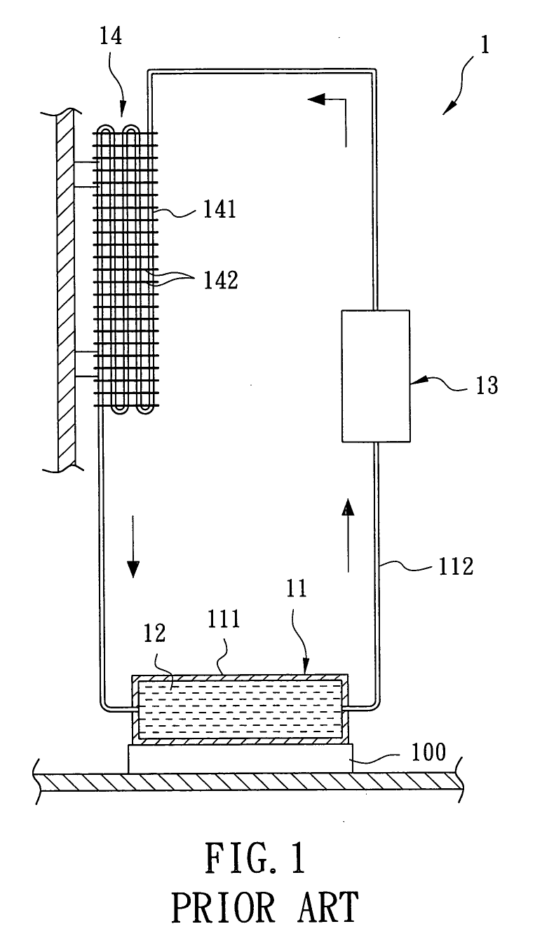

FIG. 2 is a schematic view of the preferred embodiment of a heat dissipating system according to this invention.

### DETAILED DESCRIPTION OF THE PREFERRED EMBODIMENT

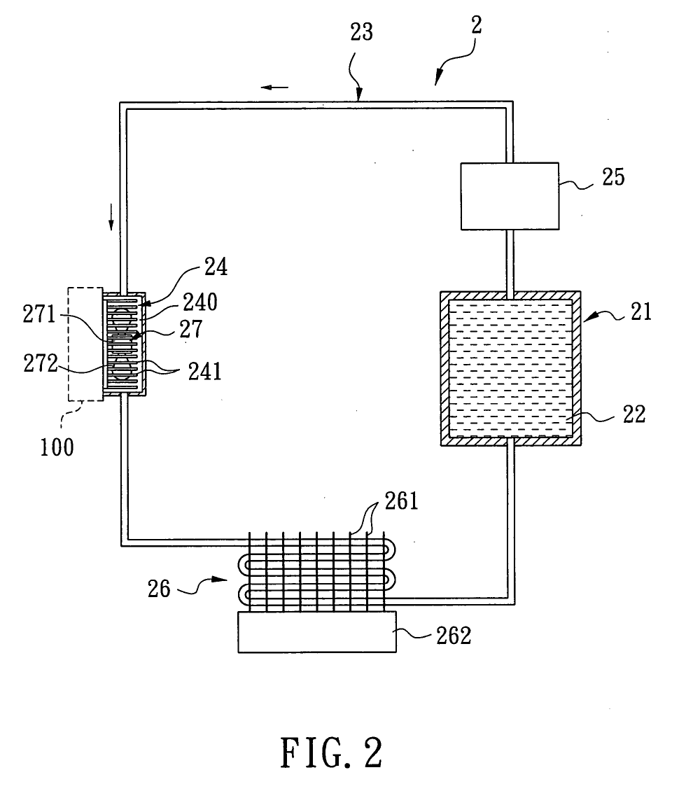

Referring to FIG. 2, the preferred embodiment of a heat dissipating system 2 according to this invention includes: a heat sink 24 adapted to be connected to an electronic device 100 for absorbing heat from the electronic device 100; a driving mechanism 25; a cooling mechanism 26; a coolant circulating conduit 23 adapted for receiving a coolant 22 therein, and connected to the heat sink 24, the driving mechanism 25, and the cooling mechanism 26 such that the driving mechanism 25 drives circulation of the coolant 22 in the coolant circulating conduit 23 through the heat sink 24 and the cooling mechanism 26 so as to transfer heat from the heat sink 24 to the cooling mechanism 26 through the coolant 22; and a fan unit 27 disposed rotatably in the heat sink 24, and driven to rotate by the coolant 22 flowing through the heat sink 24, thereby accelerating flow rate of the coolant 22 therethrough.

In this embodiment, the heat sink 24 includes a container 240 and a plurality of fins 241 disposed in the container 240. The fins 241 of the heat sink 24 surround the fan unit 27, and are in contact with the coolant 22 in the container 240. The fins 241 provide a larger surface area for heat-exchange from the electronic device 100 to the coolant 22, thereby enhancing the heat dissipating efficiency.

In this embodiment, the fan unit 27 includes a hub 271 pivoted to the heat sink 24, and blades 272 extending from the hub 271. The coolant 22 flowing through the heat sink 24 impacts the blades 272 of the fan unit 27 so as to drive the fan unit 27 to rotate. Rotation of the fan unit 24 accelerates flow of the coolant 22 through the heat sink 24, thereby promoting the heat dissipating efficiency. Moreover, rotation of the fan unit 27 generates turbulence of the coolant 22 in the heat sink 24, which results in an increase in heat exchange from the electronic device 100 to the coolant 22. It should be noted that the heat dissipating system 2 could be provided with two or more fan units in other embodiments of the invention.

In this embodiment, the driving mechanism 25 includes a pump. Preferably, the coolant 22 is water.

In this embodiment, the cooling mechanism 26 includes a plurality of fins 261 and a fan 262. The fins 261 of the cooling mechanism 26 are spaced apart from each other, and contact the coolant circulating conduit 23, such that heat is transferred to the fins 261 of the cooling mechanism 26 from the coolant 22 through the coolant circulating conduit 23. The fan 262 of the cooling mechanism 26 is used to cool the fins 261 of the cooling mechanism 26.

In operation, the heat generated by the electronic device 100 is transferred to the fins 241 of the heat sink 24. The coolant 22 passes through the heat sink 24, and absorbs heat from the fins 241 of the heat sink 24 so as to carry the heat from the heat sink 24. In addition, the fan unit 27 disposed in the container 240 of the heat sink 24 is driven by the coolant 22 flowing through the heat sink 24 so as to accelerate the flow rate of the coolant 22. The heated coolant 22 is cooled when passing through the cooling mechanism 26. The cooled coolant 22 is re-circulated to the heat sink 24 through the driving action of the pump 25, thereby continuing the heat-exchanging circulation.

Preferably, the heat dissipating system 2 further includes a reservoir 21 for receiving the coolant 22. The reservoir 21 is made from a material with low specific heat, and is connected to the coolant circulating conduit 23. The driving mechanism 25 is disposed downstream of the reservoir 21, and draws the coolant 22 from the reservoir 21 into the coolant circulating conduit 23.

In this embodiment, the electronic device 100 is directly connected to the heat sink 24. However, this invention should not be limited to the disclosed embodiment. For example, the electronic device 100 can be directly connected to the reservoir 21.

According to this invention, in view of the inclusion of the fan unit 27 in the heat dissipating system 2 of this invention, a higher efficiency of heat dissipation can be achieved as compared to the prior art.

While the present invention has been described in connection with what is considered the most practical and preferred embodiment, it is understood that this invention is not limited to the disclosed embodiment but is intended to cover various arrangements included within the spirit and scope of the broadest interpretation and equivalent arrangements.

What is claimed is:

1. A heat dissipating system adapted for cooling an electronic device, said heat dissipating system comprising:
a heat sink adapted to be connected to the electronic device for absorbing heat from the electronic device;
a driving mechanism;
a cooling mechanism;
a coolant circulating conduit adapted for receiving a coolant therein, and connected to said heat sink, said driving mechanism, and said cooling mechanism such that said driving mechanism drives circulation of the coolant in said coolant circulating conduit through said heat sink and said cooling mechanism so as to transfer heat from said heat sink to said cooling mechanism through the coolant; and
a fan unit disposed rotatably in said heat sink, and driven to rotate by the coolant flowing through said heat sink.

2. The heat dissipating system of claim 1, wherein said fan unit includes a hub pivoted to said heat sink, and blades extending from said hub.

3. The heat dissipating system of claim 1, wherein said heat sink includes a container and a plurality of fins disposed in said container and surrounding said fan unit.

4. The heat dissipating system of claim 1, wherein said cooling mechanism includes a fan and a plurality of fins spaced apart from each other and in contact with said coolant circulating conduit.

5. The heat dissipating system of claim 1, wherein said driving mechanism includes a pump.

6. The heat dissipating system of claim 1, further comprising a reservoir connected to said coolant circulating conduit for storing the coolant, said driving mechanism drawing the coolant from said reservoir into said coolant circulating conduit.
